(19) United States
(12) Patent Application Publication
(10) Pub. No.: US 2006/0044926 A1
(43) Pub. Date: Mar. 2, 2006

(54) Method and system for accessing performance parameters in memory devices

(75) Inventor: Kimmo Mylly, Julkujarvj (FI)

Correspondence Address: WARE FRESSOLA VAN DER SLUYS &;ADOLPHSON, LLP, BRADFORD GREEN BUILDING 5, 755 MAIN STREET, P O BOX 224, MONROE, CT, 06468, US

(73) Assignee: Nokia Corporation

(21) Appl. No.: 10/927,776

(22) Filed: Aug. 27, 2004

(51) Int. Cl. G11C 8/02

(52) U.S. Cl. 365/232

(57) ABSTRACT

A memory device, such as an MMC or other memory card, may support two or more different operating voltage ranges and the memory device works faster with a specific one of the ranges. A register in the memory device is used to store information indicating the specific one of ranges. As such, a host device can read the information from the memory device and adjust the programming voltage based on the specific one of ranges so as to improve the programming speed. The register can be an EXT_CSD in an MMC manufactured according to Version 4.0 or later specification. In an MMC according to an earlier specification, an additional register can be used to store that information.

### FIELD OF THE INVENTION

The present invention relates generally to a memory device and, more particularly, to the programming of such device.

### BACKGROUND OF THE INVENTION

Flash memory is a form of EEPROM (Electronically Erasable Programmable Read Only Memory) that allows multiple memory locations to be erased or written in one programming operation. Flash memory is a transistor technology and is generally classified into NOR flash and NAND flash. The names refer to the gate logic architecture of the memory cells. NOR flash memory has a longer erase and write times than NAND flash memory, but NOR flash memory has a full address/data interface that allows random access to any location. NOR is suitable for storage of program code or data that needs to be infrequently updated, as in digital cameras and PDAs.

NAND flash memory has faster erase and write times (per bytes, depending on the access), higher density and lower cost per bit than NOR flash. However, its I/O interface allows only sequential access of data. NAND flash memory is popular with flash memory cards, USB flash drives for data storage and other mass memory devices. Among those flash memory card formats are MultiMediaCard (MMC), Secure Digital (SD), Memory Stick (MS) and xD Picture card.

Although NAND flash memory is faster to write as compared to other flash technologies such as NOR, improvement of the programming performance of NAND flash memory is still desirable. As density requirements in memories are increasing and content pre-programming starts to be more routine, programming performance becomes more critical from cost point of view.

There are memory standards that can operate with two or more operating voltage ranges. For example, a dual-voltage MultiMediaCard operates both with 1.65-1.95V and 2.7-3.6V voltage ranges. Due to different memory (and controller) technologies used inside the cards, some cards may be able to store data faster with one range than the other. In production where a large amount of data is programmed to the card prior to putting it into a sales package, for example, it is advantageous and desirable to choose the optimal voltage range for access in a programming operation.

### SUMMARY OF THE INVENTION

In programming a memory device, the optimal programming parameters may differ due to different technologies used in inside different memory devices. For example, the memory device may support two different operating ranges and the memory device works faster with a specific one of the ranges. The present invention provides a method of indicating the optimal operating parameters in the memory device so as to allow programming equipment to adjust the operating parameters based on the indicated optimal parameters to achieve optimal programming performance. The optimal operating parameters specified for a memory device can be stored in one of the registers in the memory device, for example. As such, the programming equipment can obtain the optimal operating parameters by reading the contents of the registers.

In an MMC manufactured in accordance with Version 4.0 or later specification, the optimal operating parameters can be indicated in the Extended Card Specific Data (EXT_CSD) register. In a Version 3.3.1 MMC, an additional register can be implemented for storing the optimal operating parameters.

Thus, the first aspect of the present invention provides a method for improving efficiency in performing a data change in a memory device by a host device applying one or more operating parameters on the memory device, the memory device having a data access time in said data change, wherein the data access time is optimal when at least one of the operating parameters is set at a specific value for effecting said data change, said method comprising:
storing in the memory device information indicating the specific value for said at least one parameter, and
adjusting, based on the information, in the host device so that said at least one parameter is substantially equal to the specific value for performing said data change.

According to the present invention, the memory device has a plurality of registers accessible to the host device, and said information is stored in one of said registers.

According to the present invention, the memory device is operable at a plurality of voltage ranges, and the data access time is optimal when the memory device is operated at a specific one of said plurality of voltage ranges, and wherein said at least one parameter comprises said specific one of voltage ranges.

According to the present invention, the data change can be writing data in a programming operation or removing data in an erasing operation.

According to the present invention, the registers include an EXT_CSD register, and said information is stored in the EXT_CSD register.

According to the present invention, the registers include an added register, and said information is stored in the added register.

According to the present invention, the memory device is operable at two or more of the 1.65-1.95V range, the 2.0-2.6V range and the 2.7-3.6V range, and the specific one of the voltage ranges is substantially one of those ranges.

The second aspect of the present invention provides a programming system, which comprises:
a memory device; and
a host device operatively connected to the memory device for performing a data change in a memory device by applying one or more operating parameters on the memory device, the memory device having a data access time in said data change, wherein the data access time is optimal when at least one of the operating parameters is set at a specific value for effecting said data change, said memory device comprising:
a register for storing information indicating the specific value for said at least one parameter, so as to allow the host device to read the stored information and to adjust, based on the read information, said at least one parameter to be substantially equal to the specific value for performing said data change.

According to the present invention, said at least one of the operating parameters comprises a programming voltage applied to the memory device, and the specific value for the programming voltage applied to the memory device is substantially in one of the ranges of 1.65-1.95V, 2.0-2.6V or 2.7-3.6V.

According to the present invention, the register for storing information indicating the specific value is an EXT_CSD register in the memory device or an added register.

The third aspect of the present invention provides a memory device, which comprises:
a memory unit for storing data;
an interface for receiving data for effecting a data change in the memory unit in a data change operation;
a terminal for receiving a voltage at least during the data change operation, wherein the voltage can be selected from a plurality of voltage ranges and wherein said plurality of voltage ranges include one optimal range for effecting the data change; and
at least one register for storing information indicating the optimal range.

According to the present invention, said at least one register is an EXT_CSD register, or an added register.

According to the present invention, said plurality of voltage ranges include at least two of 1.65-1.95V range, 2.0-2.6V range and 2.7-3.6V range.

The fourth aspect of the present invention provides a programming module for use in conjunction with a power source for carrying out a data change in a memory device by applying a voltage on the memory device, the memory device having a data access time in said data change, wherein the data access time is optimal when the applied voltage is set at a specific value for effecting said data change, and wherein the memory device has a register for storing information indicating the specific value of the applied voltage. The programming device comprises:
means for reading the stored information in the register in the memory device, and
means for controlling the power source, based on the read information, so that the applied voltage on the memory device for effecting said data change is substantially equal to the specific value.

According to the present invention, the memory device is operable at a plurality of voltage ranges, and the specific value is substantially in one of the plurality of voltage ranges. The plurality of operable voltage ranges include at least two of 1.65-1.95V range, 2.0-2.6V range and 2.7-3.6V range.

The fifth aspect of the present invention provides an electronic device for use in conjunction with a memory device for writing and reading data in the memory device, wherein the memory device is operable at a plurality of voltage ranges and the memory device has a data access time which is optimal at a specific one of said plurality of voltage ranges, and wherein the memory device has a register for storing information indicating the specific voltage range. The electronic device comprises:
a power source for applying a voltage on the memory device; and
a processing unit, operatively connected to the memory device for reading the stored information in the register, wherein the processing unit is also operatively connected to the power source for adjusting the applied voltage, based on the read information, so that the applied voltage is substantially in the specific voltage range at least when writing data in the memory device in a programming operation or in an erasing operation.

The electronic device can be a mobile terminal or the like.

The sixth aspect of the present invention provides a software product embedded in a computer readable medium for use with a programming module for carrying out a data change in a memory device by applying a voltage on the memory device, the memory device having a data access time regarding said data change, wherein the data access time is optimal when the applied voltage is set at a specific value for effecting said data change, and wherein the memory device has a register for storing information indicating the specific value of the applied voltage. The software product comprises executable codes, which, when executed, can be used to carry out:
reading the register in the memory device for obtaining the information; and
adjusting the applied voltage, based on the information, so that the applied voltage on the memory device for effecting said data change is substantially equal to the specific value.

According to the present invention, wherein the memory device is operable a plurality of voltage ranges, such as 1.65-1.95V, 2.0-2.6V and 2.7-3.6V, and the specific value is substantially in one of the voltage ranges. The register is an EXT_CSD register in the memory device or an added register in the memory device.

The present invention will become apparent upon reading the description taken in conjunction with FIGS. 3 to 7.

### BRIEF DESCRIPTION OF THE DRAWINGS

FIG. 1 is a block diagram showing a prior art MMC architecture.

FIG. 2 is a block diagram showing another prior art MMC architecture.

FIG. 3 is a block diagram showing the MMC architecture, according to the present invention.

FIG. 4 is a block diagram showing another MMC architecture, according to the present invention.

FIG. 5 is a block diagram showing a system wherein a host connected to a memory card for programming the card.

FIG. 6 is a block diagram showing a system wherein a host connected to a plurality of memory cards for simultaneously programming the cards.

FIG. 7 is a schematic representation of an electronic device capable of programming and erasing a memory device, according to the present invention.

### DETAILED DESCRIPTION OF THE INVENTION

The memory card, in accordance with MultiMediaCard System Specification Version 3.31, has a set of information registers as shown in TABLE I. The names of the registers are: CID, RCA, DSR, CSD and OCR. The description of these registers is given in TABLE I.

TABLE I

| | | | Imple- |
|---|---|---|---|
| Name | Width | Description | mentation |
| CID | 128 | Card Identification number, a card individual | Mandatory |
| | | number for identification. | |
| RCA | 16 | Relative Card Address, is the card system | Mandatory |
| | | address, dynamically assigned by the | |
| | | host during initialization. | |
| DSR | 16 | Driver Stage Register, to configure the card's | Optional |
| | | output drivers. | |
| CSD | 128 | Card Specific Date, information about the | Mandatory |
| | | card operation conditions. | |
| OCR | 32 | Operation Conditions Register. Used by a | Mandatory |
| | | special broadcast command to identify the | |
| | | voltage type of the card. | |

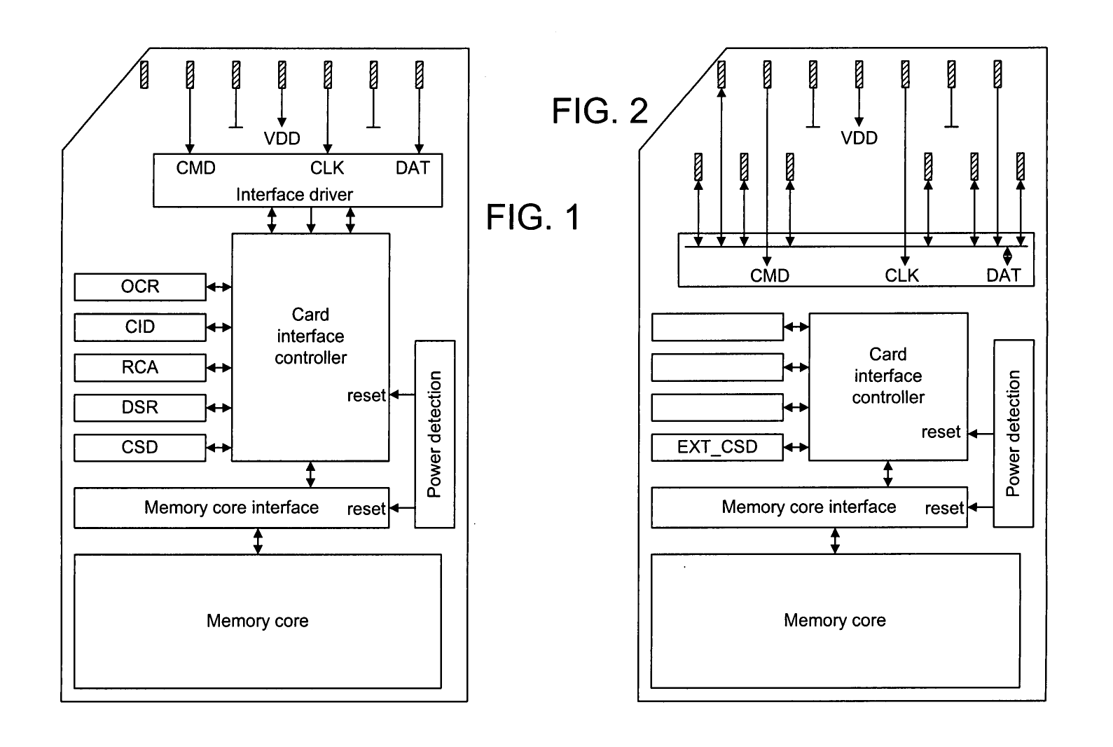

The connections between these registers with an MMC card, according to the MultiMediaCard Architecture as specified in Version 3.31 are shown in FIG. 1. The newer memory card standards, in accordance with MultiMediaCard System Specification Version 4.0, has a set of information registers as shown in TABLE II. As shown, the Version 4.0 specification includes an additional register EXT_CSD to provide information about the card capabilities and selected modes. The connections between these registers with an MMC card, according to the MultiMediaCard Architecture as specified in Version 4.0 are shown in FIG. 2.

TABLE II

| | Width | | Imple- |
|---|---|---|---|
| Name | (bytes) | Description | mentation |
| CID | 16 | Card Identification number, a card | Mandatory |
| | | individual number for identification. | |
| RCA | 2 | Relative Card Address, is the card | Mandatory |
| | | system address, dynamically assigned | |
| | | by the host during initialization. | |
| DSR | 2 | Driver Stage Register, to configure | Optional |
| | | the card's output drivers. | |
| CSD | 16 | Card Specific Date, information | Mandatory |
| | | about the card operation conditions. | |
| OCR | 4 | Operation Conditions Register. Used | Mandatory |
| | | by a special broadcast command to | |
| | | identify the voltage type of the card. | |
| EXT_CSD | 512 | Extended Card Specific Data. | Mandatory |
| | | Contains information about the card | |
| | | capabilities and selected modes. | |
| | | Introduced in specification v4.0. | |

Due to different technologies used inside different memory cards, the optimal programming parameters may differ. For example, when a memory card is operable at two or more voltage ranges, the memory card may work faster when it is operated at a specific one of the voltage ranges. The read or write/programming access may be faster with that specific voltage range. In programming the memory card, it is advantageous to use the optimal programming parameters in order to save programming time, for example.

When programming or easing a memory card operable at two or more voltage ranges, it is desirable to choose the optimal range among these ranges for data access. Thus, the host, or the equipment used for programming and erasing, should be able to read the parameters for optimum access. As such, the host can adjust the operating parameters in order to achieve the shortest possible overall programming time. According to the present invention, information regarding the optimal performance operating parameters can be specified in one of existing registers or in an additional register. In an embodiment of the present invention, an additional register 102 (OPR, denoting Optimal Performance Operating Range) is disposed in the memory card 100. The OPR register 102 is operatively connected to the card interface controller 104, along with the existing registers OCR, CID, RCA, DSR and CSD. In another embodiment of the present invention, one of the existing registers can be modified to provide the optimal range information to the host.

TABLE III

| | | | | |
|---|---|---|---|---|
| | | Size | | CSD- |
| Name | Field | (Bytes) | Cell Type | slice |

Properties Segment

| | | | | |
|---|---|---|---|---|
| Reserved | | 7 | | [511:505] |
| Supported Command Sets | S_CMD_SET | 1 | R | [504] |
| Reserved | | 300 | | [503:204] |
| Power Class for 26 MHz @ 3.6 V | PWR_CL_26_360 | 1 | R | [203] |
| Power Class for 52 MHz @ 3.6 V | PWR_CL_52_360 | 1 | R | [202] |
| Power Class for 26 MHz @ 1.95 V | PWR_CL_26_195 | 1 | R | [201] |
| Power Class for 52 MHz @ 1.95 V | PWR_CL_52_195 | 1 | R | [200] |

As shown in TABLE III, the existing EXT_CSD has a number of reserved properties segments. One of the reserved segments can be used to provide the optimal-range information to the host, for example. The illustrative implementation of the present invention is shown in TABLE IV.

TABLE IV

| | | | | |
|---|---|---|---|---|
| | | Size | Cell | CSD- |
| Name | Field | (Bytes) | Type | slice |

Properties Segment

| | | | | |
|---|---|---|---|---|
| Reserved | | 7 | | [511:505] |
| Supported Command Sets | S_CMD_SET | 1 | R | [504] |
| Reserved | | 300 | | [503:204] |
| Power Class for 26 MHz @ 3.6 V | PWR_CL_26_360 | 1 | R | [203] |
| Power Class for 52 MHz @ 3.6 V | PWR_CL_52_360 | 1 | R | [202] |
| Power Class for 26 MHz @ 1.95 V | PWR_CL_26_195 | 1 | R | [201] |
| Power Class for 52 MHz @ 1.95 V | PWR_CL_52_195 | 1 | R | [200] |
| Optimal Performance Operating | OP_PERF_RANGE | 1 | R | [205] |
| Range | | | | |

The new properties segment can be called Optimal Performance Operation Range, with the corresponding field called OP_PERF_RANGE. The EXT_CSD register, so modified, is shown in FIG. 4. As shown in FIG. 4, only the content of the EXT-CSD register 112 is modified to include the optimal range information. Its relation to the card interface controller 114 remains unchanged.

In an 8-bit register, it is possible to assign bit0 to mean that 1.8V is the higher performance voltage range. Likewise, bit1 can be set to inform the host that 3.0V is the higher performance voltage range. All of the other bits can be reserved if the memory card is operable at two voltage ranges.

Alternatively, a number of bits in the OCR register can be used to specify the optimal voltage range. The OCR register, according to both Version 3.31 and Version 4.0, is shown in TABLE V.

TABLE V

| | VDD voltage | High Voltage | Dual Voltage |
|---|---|---|---|
| OCR bit | window | MultiMediaCard | MultiMediaCard |
| [6:0] | Reserved | 000 0000b | 00 00000b |
| [7] | 1.65-1.95 | 0b | 1b |
| [14:8] | 2.0-2.6 | 000 0000b | 000 0000b |
| [23:15] | 2.7-3.6 | 1 1111 1111b | 1 1111 1111b |
| [30:24] | Reserved | 000 0000b | 000 0000b |

| | |
|---|---|
| [31] | card power up status bit (busy)1 |

As shown in TABLE V, bit0-bit6 and bit24-bit30 are reserved. It is possible to use two of the reserved bits, bit24 and bit26 for example, to specify the higher performance voltage range as follows:
00=Not defined (backward compatibility)
01=1.8V being the higher performance voltage range
10=3V being the higher performance voltage range.

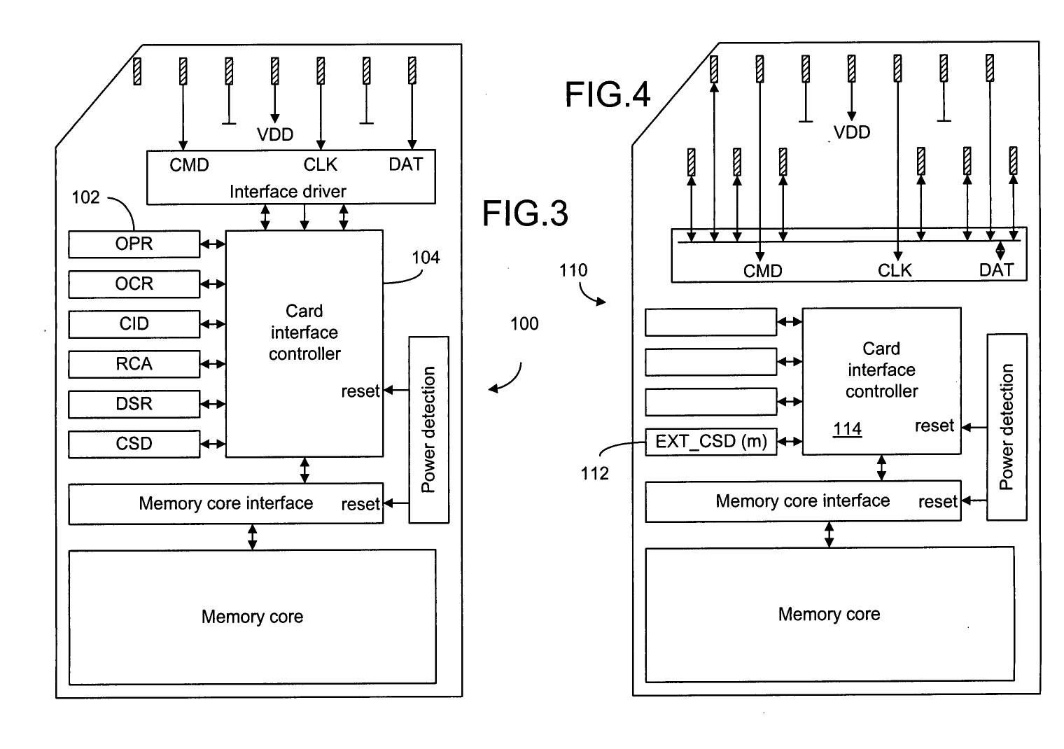

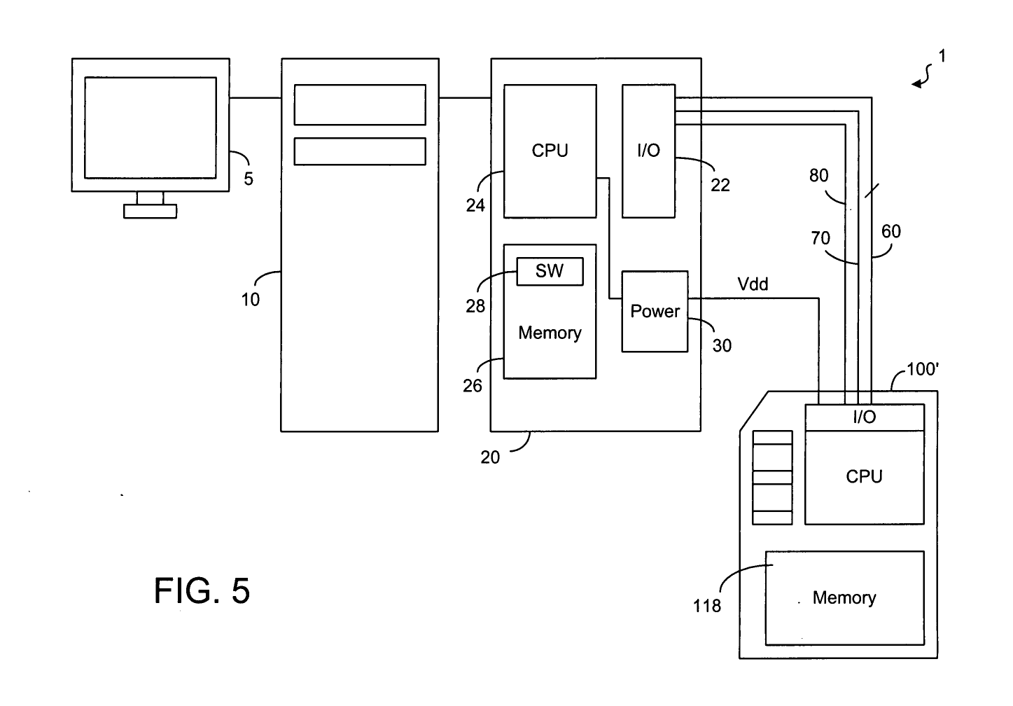

In order to allow the host to obtain the information indicative of the optimal voltage range, or the optimal operating parameters in general, from the memory card, it is possible to put a code in the controlling software in the host equipment so as to allow the host equipment to recognize the optimal operating parameters. FIG. 5 is a block diagram showing a system for programming one or more memory cards. As shown, the system 1 comprises a PC 10 which controls the overall programming system. The PC 10 is operatively connected to a programming device 20 for controlling the programming operations. The programming device 20 comprises an I/O interface 22 operatively connected to a memory device 100′ via a data bus 60, a command line (CMD) 70 and a clock line 80. The memory device 100′ has a memory unit for storing data programmed by the programming device 20. The programming device 20 has a memory unit 26 for storing data to be programmed to the memory device 100′ under the control of a CPU 24. The memory unit 26 includes a software program 28 for the programming code. The programming device 20 further includes a power supply 30 operatively connected to the memory device 100′ for providing the programming voltage Vdd. If the memory device is an MMC 100 as shown in FIG. 3, the CPU 24 of the programming device 20 reads the optimal operating parameters from the OPR register 102 through the data lines 60 and the I/O interfaces 101, 22. If the memory device 100′ is a MMC 110 as shown in FIG. 4, the CPU 24 reads the optimal operating parameters from the modified EXT_CSD register 112. After reading the optimal operating parameters for access, the CPU 24 adjusts the programming parameters in the memory unit 26. One of the programming parameters is the programming voltage Vdd, which can be selected between a first range of 1.65-1.95V and a second range of 2.7-3.6V, for example. But Vdd can also be in a third range of 2.0-2.6V. After reading information indicating the optimal voltage range for programming or erasing the memory device from the relevant register in the memory device 100′, the CPU 24 in the programming device 20 adjusts on the power supply 30 the programming voltage Vdd to the optimal voltage range. After setting the parameters, programming of the memory device 100 can start. As shown in FIG. 5, the PC is connected to a display 5 for showing the status of the programming operation.

It should be noted that the software program 28 can be a software product embedded in a computer readable medium for use with the programming device 20 for programming or erasing in the memory device 100′. The software product comprises executable codes, which, when executed, can be used to read the register in the memory device for obtaining the information indicating he optimal voltage range; and to adjust the programming voltage Vdd, based on the information, so that the programming voltage on the memory device for effecting said data change is substantially equal to a value within the optimal voltage range.

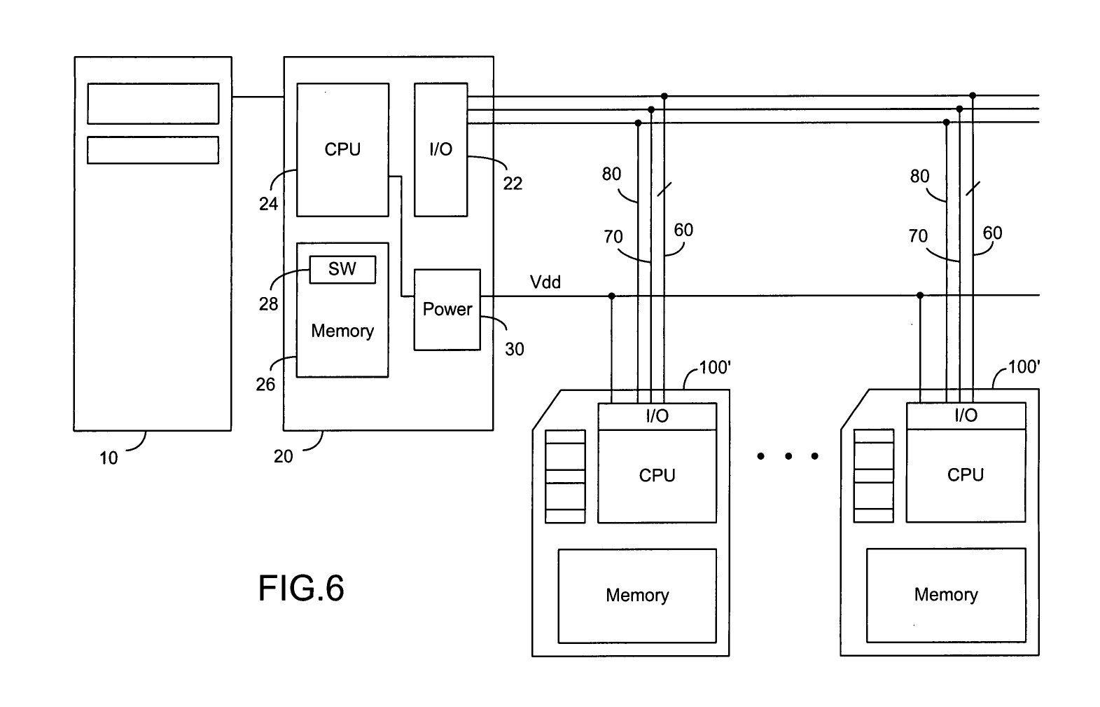

In general, one programming device 20 can be used to simultaneously program or erase a plurality of memory devices 100′, as shown in FIG. 6.

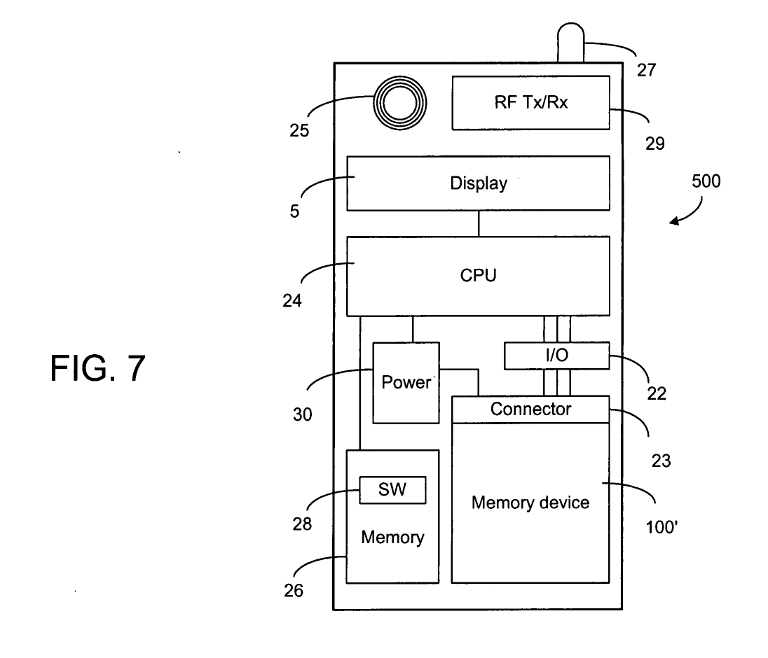

FIG. 7 is a schematic representation of an electronic device capable of programming and erasing a memory device, according to the present invention. As shown in FIG. 7, the electronic device 500 has a connector 23 to accept a memory device 100′ onto which data can be written in the electronic device and from which data can be read in the electronic device. The electronic device has a display 5, a CPU 24, a power source 30, an internal memory unit 26 with a software program 28 and an interface 22, similar to those depicted in FIGS. 5 and 6. Some of these components can be used to program or erase the memory device as described in conjunction with the host device 20 in FIG. 5. However, the electronic device 500 can have communications capability so it can be used as a communications device, such as a mobile terminal. Furthermore, the electronic device 500 can be equipped with an imaging module 25 (optical components and a CCD chip, for example) so pictures can be taken through the optical component and stored in the memory device 100′. In that respect, the electronic device 500 can be a digital camera. Pictures stored in the memory device 100′ can be displayed on the display 5 or sent to a remote site via an antenna 27 and an RF front end 29. The method of improving the efficiency in programming a memory device, according to the present invention, is particularly useful when a large amount of data, such as image data is written into the memory device.

In sum, when a memory device, such as an MMC or a NAND packet, is operable at a plurality of voltage ranges and the data access time is optimal when the memory device is operated at one of the voltage ranges, it is possible to store information in one of the registers in the memory device indicating the optimal voltage range. A host device reads the stored information so that it can adjust the programming/erasing voltage based on the information in order to improve the programming/erasing speed. The register can be an existing register, such as the EXT_CSD register, or an added register. The host device can be a programming module connected to a PC or a standalone electronic device.

Thus, although the invention has been described with respect to one or more embodiments thereof, it will be understood by those skilled in the art that the foregoing and various other changes, omissions and deviations in the form and detail thereof may be made without departing from the scope of this invention.

What is claimed is:

1. A method for improving efficiency in performing a data change in a memory device by a host device applying one or more operating parameters on the memory device, the memory device having a data access time in said data change, wherein the data access time is optimal when at least one of the operating parameters is set at a specific value for effecting said data change, said method comprising:
storing in the memory device information indicating the specific value for said at least one parameter, and
adjusting, based on the information, in the host device so that said at least one parameter is substantially equal to the specific value for performing said data change.

2. The method of claim 1, wherein the memory device has a plurality of registers accessible to the host device, and wherein said information is stored in one of said registers.

3. The method of claim 1, wherein the memory device is operable at a plurality of voltage ranges, and the data access time is optimal when the memory device is operated at a specific one of said plurality of voltage ranges, and wherein said at least one parameter comprises said specific one of voltage ranges.

4. The method of claim 1, said data change comprises writing data in a programming operation.

5. The method of claim 1, said data change comprises removing data in an erasing operation.

6. The method of claim 2, wherein the registers include an EXT_CSD register, and wherein said information is stored in the EXT_CSD register.

7. The method of claim 2, wherein the registers include an added register, and wherein said information is stored in the added register.

8. The method of claim 3, wherein the specific one of the voltage ranges is substantially equal to 1.65-1.95V.

9. The method of claim 3, wherein the specific one of the voltage ranges is substantially equal to 2.0-2.6V.

10. The method of claim 3, wherein the specific one of the voltage ranges is substantially equal to 2.7-3.6V.

11. A programming system comprising:
a memory device; and
a host device operatively connected to the memory device for performing a data change in a memory device by applying one or more operating parameters on the memory device, the memory device having a data access time in said data change, wherein the data access time is optimal when at least one of the operating parameters is set at a specific value for effecting said data change, said memory device comprising:
a register for storing information indicating the specific value for said at least one parameter, so as to allow the host device to read the stored information and to adjust, based on the read information, said at least one parameter to be substantially equal to the specific value for performing said data change.

12. The programming system of claim 11, wherein said at least one of the operating parameters comprises a programming voltage applied to the memory device.

13. The programming system of claim 12, wherein the specific value for the programming voltage applied to the memory device is substantially in the range of 1.65-1.95V.

14. The programming system of claim 12, wherein the specific value for the programming voltage applied to the memory device is substantially in the range of 2.0-2.6V.

15. The programming system of claim 12, wherein the specific value for the programming voltage applied to the memory device is substantially in the range of 2.7-3.6V.

16. The programming system of claim 12, wherein the register for storing information indicating the specific value is an EXT_CSD register in the memory device.

17. The programming system of claim 12, wherein the register for storing information indicating specific value is an added register in the memory device.

18. A memory device comprising:
a memory unit for storing data;
an interface for receiving data for effecting a data change in the memory unit in a data change operation;
a terminal for receiving a voltage at least during the data change operation, wherein the voltage can be selected from a plurality of voltage ranges and wherein said plurality of voltage ranges include one optimal range for effecting the data change; and
at least one register for storing information indicating the optimal range.

19. The memory device of claim 18, wherein said at least one register is an EXT_CSD register.

20. The memory device of claim 18, wherein said plurality of voltage ranges include at least two of 1.65-1.95V range, 2.0-2.6V range and 2.7-3.6V range.

21. A programming module for use in conjunction with a power source for carrying out a data change in a memory device by applying a voltage on the memory device, the memory device having a data access time in said data change, wherein the data access time is optimal when the applied voltage is set at a specific value for effecting said data change, and wherein the memory device has a register for storing information indicating the specific value of the applied voltage, said programming device comprising:
means for reading the stored information in the register in the memory device, and
means for controlling the power source, based on the read information, so that the applied voltage on the memory device for effecting said data change is substantially equal to the specific value.

22. The programming module of claim 21, wherein the memory device is operable at a plurality of voltage ranges, and the specific value is substantially in one of the plurality of voltage ranges.

23. The programming module of claim 21, wherein the plurality of operable voltage ranges include at least two of 1.65-1.95V range, 2.0-2.6V range and 2.7-3.6V range.

24. The programming module of claim 21, wherein the register for storing information indicating the specific value is an EXT_CSD register in the memory device.

25. The programming module of claim 21, wherein the register for storing information indicating specific value is an added register in the memory device.

26. An electronic device for use in conjunction with a memory device for writing and reading data in the memory device, wherein the memory device is operable at a plurality of voltage ranges and the memory device has a data access time which is optimal at a specific one of said plurality of voltage ranges, and wherein the memory device has a register for storing information indicating the specific voltage range, said electronic device comprising:
a power source for applying a voltage on the memory device; and
a processing unit, operatively connected to the memory device for reading the stored information in the register, wherein the processing unit is also operatively connected to the power source for adjusting the applied voltage, based on the read information, so that the applied voltage is substantially in the specific voltage range at least when writing data in the memory device.

27. The electronic device of claim 26, wherein the applied voltage is substantially in the specific voltage range when writing data in the memory device in a programming operation.

28. The electronic device of claim 26, wherein the applied voltage is substantially in the specific voltage range when writing data in the memory device in an erasing operation.

29. The electronic device of claim 26, wherein said plurality of voltage ranges include at least two of 1.65-1.95V range, 2.0-2.6V range and 2.7-3.6V range.

30. The electronic device of claim 26, comprises a mobile terminal.

31. A software product embedded in a computer readable medium for use with a programming module for carrying out a data change in a memory device by applying a voltage on the memory device, the memory device having a data access time regarding said data change, wherein the data access time is optimal when the applied voltage is set at a specific value for effecting said data change, and wherein the memory device has a register for storing information indicating the specific value of the applied voltage, said software product comprising executable codes, which, when executed, are used to carry out:
reading the register in the memory device for obtaining the information; and
adjusting the applied voltage, based on the information, so that the applied voltage on the memory device for effecting said data change is substantially equal to the specific value.

32. The software product of claim 31, wherein the memory device is operable at a plurality of voltage ranges, including at least two of 1.65-1.95V range, 2.0-2.6V range and 2.7-3.6V range, and the specific value is substantially a value in one of said plurality of voltage ranges.

33. The software product of claim 31, wherein the register in the memory device is an EXT_CSD register.

34. The software product of claim 31, wherein the register in the memory device is an added register.
